(19) United States
(12) Patent Application Publication
(10) Pub. No.: US 2002/0185698 A1
(43) Pub. Date: Dec. 12, 2002

(54) Gate for preventing dopants from penetrating a gate insulator and method of forming the same

(76) Inventors: Chung-Ching Lai, Taipei (TW); Jui-Ping Li, Ilan Hsien (TW); Tung-Ming Lai, Taipei Hsien (TW); Chien-Nan Tu, Kaohsiung (TW)

Correspondence Address: BIRCH STEWART KOLASCH & BIRCH, PO BOX 747, FALLS CHURCH, VA, 22040-0747, US

(21) Appl. No.: 09/986,726

(22) Filed: Nov. 9, 2001

(30) Foreign Application Priority Data
Jun. 8, 2001 (TW) 90113933

(51) Int. Cl. H01L 29/76

(52) U.S. Cl. 257/412

(57) ABSTRACT

A gate for preventing dopants from penetrating a gate insulator comprises a polysilicon layer and an amorphous-silicon layer disposing on the polysilicon layer. The layered gate inhibits dopants from penetrating through a gate oxide layer disposing between the gate and a substrate. A source and a drain are disposed in the substrate beside the amorphous-silicon layer and the polysilicon layer.

### BACKGROUND OF THE INVENTION

1. Field of the Invention

The present invention relates in general to a gate and a method for forming the gate. More particularly, the present invention relates to a gate for preventing dopants from penetrating a gate insulator and method of forming the same.

2. Description of Related Prior Arts

Metal-oxide-semiconductor transistors (MOS transistor) comprising a gate, a drain and a source are a common electronic element used in integrated circuits (ICs). The MOS transistor can be a digitalized solid switch and applied in logic and IC products. There are three types of MOS transistor: NMOS, PMOS and complementary MOS (CMOS). The CMOS is composed of a NMOS and a PMOS.

In general, the PMOS is formed by the following steps. A gate oxide layer 12 is formed on the silicon substrate 10. A polysilicon layer 14 is deposited and defined to form a gate. Boron ions are then implanted in the gate and in the silicon substrate 10 to form source/drain 20. The boron ions are distributed over the upper portion of the gate, as shown in FIG. 1A, and the boron ions diffuse into the grain and along the grain boundary when performing the anneal process to activate the dopants under high temperature. However, the diffusion rate of the boron ions in the grain boundary is faster than that of the boron ions in the grain, so the dopants diffuse along the grain boundary and arrive in the gate oxide layer 12, as shown in FIG. 1B. After the dopants inside the grains are activated, the anneal process is finished. Because there are a lot of dopants accumulated in the grain boundary near the gate oxide layer 12, the dopants (boron ions) penetrate the gate oxide layer 12 easily, as shown in FIG. 1C. If the gate oxide layer 12 is too thin, the dopants penetrate the gate oxide layer 12 easily before the dopants inside the grains are activated, as shown in FIG. 2.

If the dopants penetrate the gate oxide layer, it affects the quality of the gate oxide layer, and the reliability and lifetime of the device are reduced. There are two traditional ways to resolve the above-mentioned problem. One way is to reduce the diffusion rate of the boron ions in the polysilicon layer. The other is to strengthen the gate oxide layer to resist the penetration of boron.

In this invention, the former method is used.

For example, Yu et al., in U.S. Pat. No. 6,162,716 disclose a method for forming a multiple layer amorphous silicon gate with mismatched grain boundaries to confine the ions within the amorphous silicon and inhibit the penetration of the ions into the underlying gate oxide.

Further, Liao et al., in U.S. Pat. No. 5,652,156 disclose a method of forming a multilayered polysilicon gate which inhibits the penetration of the ions into the underlying gate oxide. A layer of amorphous silicon is formed overlying the gate silicon oxide layer and a layer of polysilicon is formed over the amorphous silicon layer, wherein silicon grain boundaries of the polysilicon layer are misaligned with silicon grain boundaries of the amorphous silicon layer.

### SUMMARY OF THE INVENTION

Thus, the present invention provides a method to fabricate a gate without boron penetration the gate oxide layer.

The present invention provides a gate for preventing dopants from penetrating a gate insulator. The gate is a stacked structure comprising a polysilicon layer and an amorphous-silicon layer. The source and the drain are disposed beside the gate in the substrate.

The present invention provides a method of forming a gate for preventing dopants from penetrating a gate insulator, comprising: providing a substrate; forming a gate insulator on the substrate; forming a polysilicon layer on the gate insulator; forming an amorphous-silicon layer on the polysilicon layer; and patterning the polysilicon layer and the amorphous-silicon layer to form a gate.

The gate insulator can be a gate oxide layer. The thickness of the polysilicon layer is about 300˜1000 Å. The polysilicon layer can be formed by low pressure chemical vapor deposition with silane as a processing gas under 0.15˜0.25 torr at 580˜630° C. The thickness of the amorphous-silicon layer 106 is about 1000˜2000 Å. The amorphous-silicon layer 106 can be formed by low pressure chemical vapor deposition with silane as a processing gas under 0.15˜0.25 torr at 510˜560° C.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIGS. 1A˜1C are cross-sectional views of a gate illustrating the step of implanting boron ions in a semiconductor substrate and the diffusion of boron ions according to the prior art.

FIG. 2 is a cross-sectional view of a gate with a thin gate oxide layer illustrating the diffusion of boron ions according to the prior art.

FIGS. 3A˜3D are cross-sectional views of a gate illustrating the step of implanting dopants in a semiconductor substrate without dopant penetration.

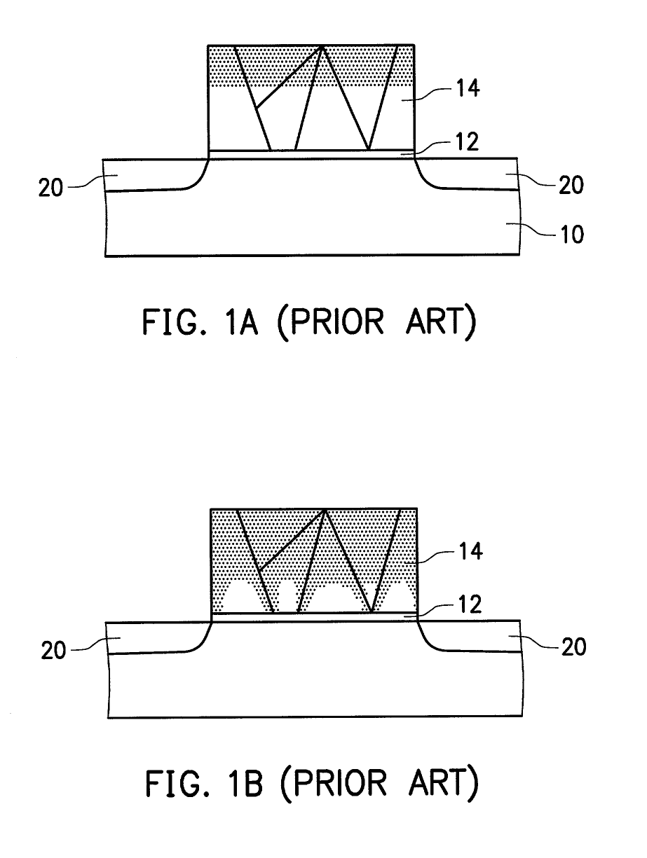

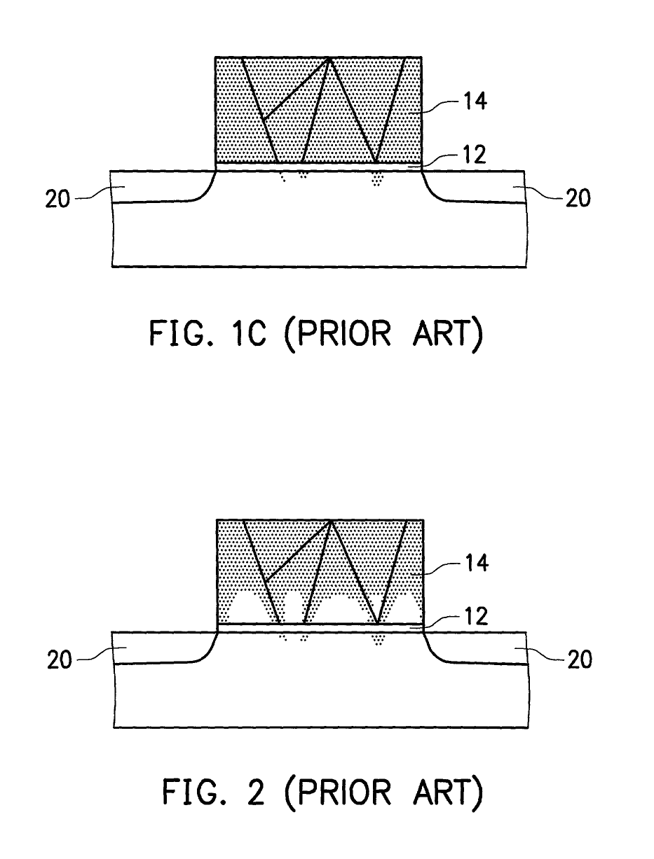

### DETAILED DESCRIPTION OF THE PREFERRED EMBODIMENT

The present invention will be described in detail with reference to the drawings. The purpose of the present invention is to provide a method for fabricating a gate with a stacked structure comprising a polysilicon layer and an amorphous-silicon layer. The amorphous-silicon layer of the gate structure can prevent the dopants from penetrating, so as to ensure gate oxide layer quality. To clearly illustrate the present invention, a detailed embodiment is described as follows.

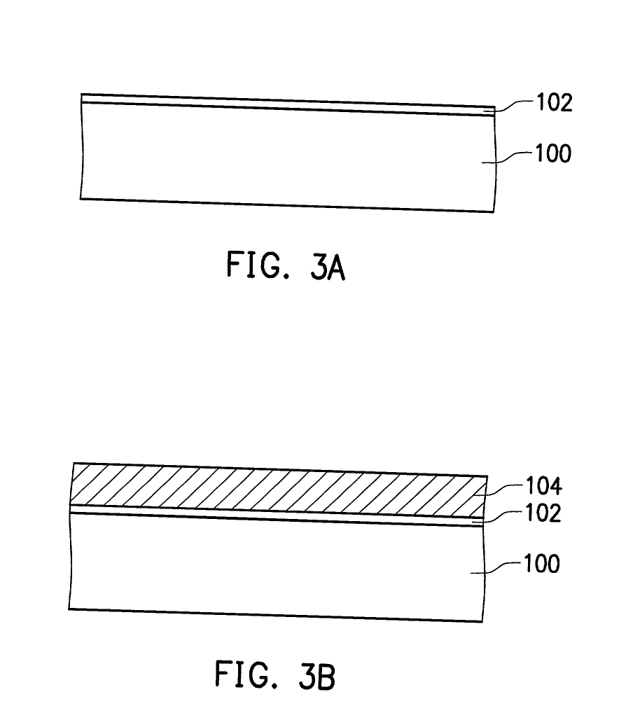

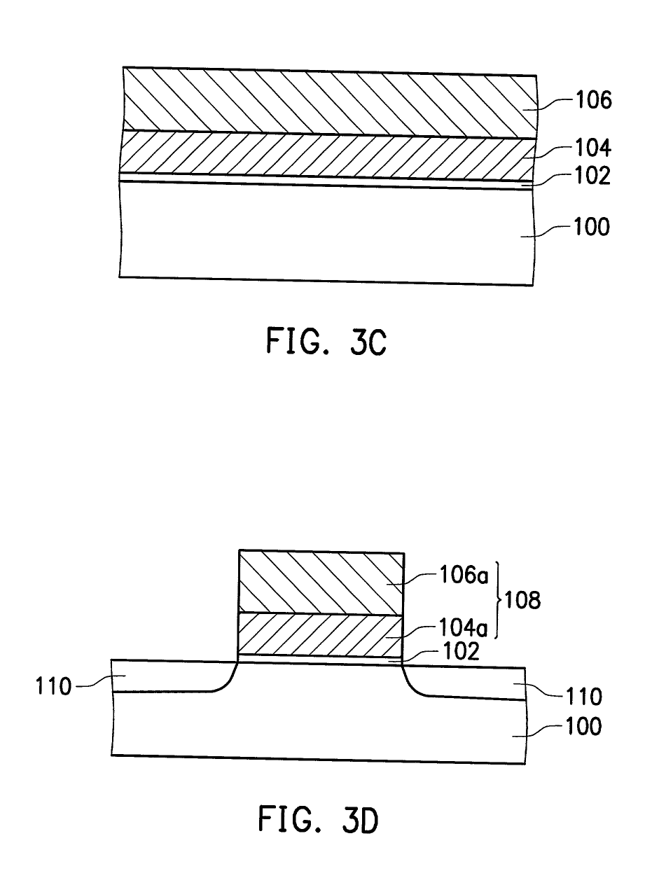

Please refer to FIG. 3A. A substrate 100, such as silicon semiconductor substrate, is provided. A gate insulator 102, such as a gate oxide layer, is formed on the substrate 100. In 0.18 μm processes, the thickness of the gate oxide layer is about 30 Å, and the gate oxide layer can be formed by thermal oxidation or by chemical vapor deposition.

Referring to FIG. 3B, a polysilicon layer 104 is formed on the gate insulator 102. The thickness of the polysilicon layer 104 is about 300˜1000 Å. The polysilicon layer 104 can be formed by low pressure chemical vapor deposition with silane as a processing gas under 0.15˜0.25 torr at 580˜630° C.

Turning to FIG. 3C, an amorphous-silicon layer 106 is formed on the polysilicon layer 104. The thickness of the amorphous-silicon layer 106 is about 1000˜2000 Å. The amorphous-silicon layer 106 can be formed by low pressure chemical vapor deposition with silane as a processing gas under 0.15˜0.25 torr at 510˜560° C.

As shown in FIG. 3D, the amorphous-silicon layer 106 and the polysilicon layer 104 are patterned and transferred to the amorphous-silicon layer 106a and the polysilicon layer 104a, which are a gate 108. An ion implanting process is performed to form source/drain 110 beside the gate 108 in the substrate 100. Using PMOS as an example, the dopants are boron ions, the dosage is about 1×10¹⁵˜1×10¹⁶ cm⁻², and the implant energy is about 3˜20 keV. For NMOS, the dopants are arsenic ions, the dosage is about 1×10¹⁵1×10¹⁶ cm⁻², and the implant energy is about 30˜80 keV. An anneal process is performed to activate the dopants.

It is noted that, in this preferred embodiment, the upper portion of the gate 108, the amorphous-silicon layer 106a, effectively prevents dopant penetration, thereby improving gate reliability.

The above-mentioned source/drain can be lightly doped drain (LDD) or other types.

Summing up the embodiment, the invention provides benefits of (1) the amorphous-silicon layer slowing down the diffusion rate of dopants so as to prevent the dopants penetrating the gate insulator even into the substrate; (2) the quality of the gate insulator and device reliability and lifetime are improved by using the stacked polysilicon layer and amorphous-silicon layer; (3) the method can be used to fabricate not only PMOS but also NMOS; and (4) the method can apply to logic and memory processes.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A gate for preventing dopants from penetrating a gate insulator, comprising:
a gate insulator disposed on a substrate;
a polysilicon layer disposed on the gate insulator; and
an amorphous-silicon layer disposed on the polysilicon layer, wherein the gate is composed of the polysilicon layer and the amorphous-silicon layer.

2. The gate as claimed in claim 1, wherein the gate insulator 23 is a gate oxide layer.

3. The gate as claimed in claim 11 wherein the thickness of the polysilicon layer is 300˜1000 Å.

4. The gate as claimed in claim 3, wherein the thickness of the amorphous-silicon layer is 1000˜2000 Å.

5. A method of forming a gate for preventing dopants from penetrating a gate insulator, comprising:
providing a substrate;
forming a gate insulator on the substrate;
forming a polysilicon layer on the gate insulator;
forming an amorphous-silicon layer on the polysilicon layer; and
patterning the polysilicon layer and the amorphous-silicon layer to form a gate.

6. The method as claimed in claim 5, wherein the gate insulator is a gate oxide layer.

7. The method as claimed in claim 5, wherein the thickness of the polysilicon layer is 300-1000 Å.

8. The method as claimed in claim 7, wherein the method of forming the polysilicon layer comprises using silane as a processing gas to deposit the polysilicon layer under 0.15˜0.25 torr at 580˜630° C.

9. The method as claimed in claim 5, wherein the thickness of the amorphous-silicon layer is 1000˜2000 Å.

10. The method as claimed in claim 9, wherein the method of forming the amorphous-silicon layer comprises using silane as a processing gas to deposit the amorphous-silicon layer under 0.15˜0.25 torr at 510˜560° C.

11. The method as claimed in claim 5, wherein after the step of patterning the polysilicon layer and the amorphous-silicon layer to form the gate, a source/drain is formed in the substrate beside the gate by ion implantation.

12. The method as claimed in claim 11, wherein after performing the ion implanting, an anneal process is performed.

13. The method as claimed in claim 11, wherein a dopant used in the ion implanting process is boron ions.

14. The method as claimed in claim 13, wherein in the implantation of boron ions, the dosage is 1×10¹⁵˜1×10¹⁶ cm⁻² and the implant energy is 3˜20 keV.

15. The method as claimed in claim 11, wherein a dopant used in the ion implanting process is As ions.

16. The method as claimed in claim 15, wherein in the implantation of As ions, the dosage is 1×10¹⁵˜1×10¹⁶ cm⁻² and the implant energy is 30-80 keV.
